(19) United States
(12) Patent Application Publication
(10) Pub. No.: US 2009/0045824 A1
(43) Pub. Date: Feb. 19, 2009

(54) PROXIMITY SENSOR WITH AN EDGE CONNECTION, AND METHOD FOR MANUFACTURING THE SAME

(76) Inventors: Malcolm F. Douglas, Wales (GB); David Cook, Berkshire (GB); Richard A. Loyd, Oxfordshire (GB)

Correspondence Address: 3M INNOVATIVE PROPERTIES COMPANY, PO BOX 33427, ST. PAUL, MN, 55133-3427, US

(21) Appl. No.: 12/161,419

(22) PCT Filed: Jan. 19, 2007
(86) PCT No.: PCT/US2007/001392

§ 371 Date: Oct. 16, 2008

(30) Foreign Application Priority Data
Jan. 19, 2006 (EP) 06001149.1

(51) Int. Cl. G01R 27/26

(52) U.S. Cl. 324/688

(57) ABSTRACT

A capacitive proximity sensor is described for mounting to a body for sensing external objects. The sensor comprises a dielectric film substrate (2) having front and rear major surfaces which, in use of the sensor, face respectively outward from and towards the body; a sensor conductor (6) on the front major surface, and a guard conductor (8) on the rear major surface to provide an electrical shield for the sensor conductor. The sensor is configured so that electrical contact can be made to the sensor conductor and to the guard conductor at the edge of the film substrate. In one embodiment, this is achieved through the provision of a tongue portion (5) which extends from a peripheral edge (4a) of a main part (4) of the substrate, and onto which the sensor and guard conductors extend to provide respective terminals (10, 12) by which external electrical connections can be made to the sensor.

### FIELD

The present disclosure relates to a capacitive sensor film for mounting to a body, for example to detect the presence of an external object. The present disclosure also relates to an improved method for manufacturing such capacitive sensor films.

### BACKGROUND

Capacitive proximity sensors have been used in various industrial applications for locating the presence of objects or materials. Various forms of capacitive proximity sensors are known and are suitable for use in different environments and applications including, for example, touch-operated systems, collision-prevention systems, occupancy-detection systems, and security/warning systems. In one field of application, capacitive proximity sensors have been fitted, for example, with the rear side and/or bumpers of cars. When the vehicle is reversed a warning signal is provided when the car approaches an object so that a collision can be safely avoided while still allowing the driver to conveniently position the car close to such object.

GB 2,400,666 discloses a capacitive proximity sensor comprising a substrate bearing two metal plates on its opposite major surfaces. The capacitive proximity sensor can be provided inside the bumper of a vehicle. The metal plate facing outwardly is referred to as the sensor conductor whereas the metal plate facing the car body is called the guard conductor. The sensor conductor is screen-printed with conductive ink onto the substrate whereas the guard conductor may be a metal strip. The guard conductor is typically larger than the sensor conductor and provides a shield between the sensor conductor and the car body. The change of the capacitance between the sensor conductor and ground is monitored and provides an indication for the distance between the car and the object.

Controlling devices for capacitive sensors are disclosed, for example, in GB 2,396,015 and in WO 02/19,524.

GB 2,374,422 addresses the problem of reducing the sensitivity of a capacitive proximity sensor to very close objects that the sensor is not required to detect. Specifically, in the case of a sensor on a vehicle bumper, GB 2,374,422 addresses the problem of reducing the effect of the presence of water as caused, for example, by steady rain. In one embodiment it is suggested to arrange an extra conductive plate on the major side of the substrate bearing the sensor conductor. The extra conductive plate, which can be arranged on the sensor conductor side above or below said sensor conductor or both (with respect to the level of the street), is often referred to as superguard conductor. In operation, an amplified guard signal is applied to the superguard conductor, which has the effect of making the guard appear bigger. The superguard conductor is effective in attenuating or minimizing capacitance changes resulting from drips of water running across the front of the sensor. A capacitive proximity sensor comprising a superguard conductor is also disclosed in GB 2,404,443.

GB 2,348,505 discloses a sensor conductor geometry where the end regions of such conductor may be wider than its central position. This tends to improve the sensitivity of the capacitive proximity sensor at the corners of the vehicle.

GB 2,386,958 discloses an integral capacitive sensor for proximity detection, which is integrally moulded into either the back face or the middle of the bumper of a car.

U.S. Pat. No. 5,801,340 discloses a capacitive sensor for detecting the pressure of an object in a sensing region which has a relatively complicated construction and comprises, in the sequence given, a conductive ground plate, an insulator, a conductivity guard layer, an insulator and a conductive touch or sensing plate followed by another insulator.

US 2002/0,158,582 discloses a capacitive sensor for automotive applications comprising an essentially non-conductive protective screen, an electrically insulating film situated behind said protective screen and having two faces each of which is coated at least in part with an electrically conductive material.

The capacitive sensors discussed so far do not meet all practical requirements to a sufficient degree. Electrical contact is typically made to the conductor plates on the opposite surfaces of the substrate from both sides of the capacitive sensor device which renders the incorporation of the sensor device in the desired location, for example, into the bumper of a car more complicated and adversely affects the reliability of the sensor device during its lifetime. The methods of manufacturing capacitive proximity sensors disclosed in the prior art include, for example, screen-printing or coating of the conductor plates which is expensive and hence does not meet the requirements of mass production. Other conventional capacitive proximity sensor constructions require a mechanical anchoring, which may add costs and is less desirable from a processing point of view.

Accordingly, in some embodiments, the present disclosure provides a capacitive proximity sensor device, which does not exhibit the shortcomings of the state-of-the-art devices or exhibits them to a lower degree only. In some embodiments, the present disclosure provides a capacitive sensor device which can be electrically contacted easily and reliably. In some embodiments, the present disclosure provides a method of manufacturing capacitive proximity sensors which is improved in comparison to state-of-the-art methods and complies with the requirements of mass production. Other features and advantages of various embodiments of the present disclosure can readily be taken from the following detailed description.

### SUMMARY

The present disclosure relates to a capacitive proximity sensor for mounting to a body for sensing external objects, the sensor comprising a dielectric film substrate having front and rear major surfaces which, in use of the sensor, face respectively outward from and towards the body; a sensor conductor on the front major surface, and a guard conductor on the rear major surface to provide an electrical shield for the sensor conductor; wherein electrical contact can be made to the sensor conductor and to the guard conductor at the edge of the film substrate.

The present disclosure furthermore relates more particularly, but not exclusively, to the use of a capacitive proximity sensor of the present disclosure for automotive applications.

### BRIEF DESCRIPTION OF THE FIGURES

Embodiments of the disclosure will now be described, by way of example only, with reference to the accompanying drawings in which:

FIG. 1 shows a top view of the front major surface of the backing layer 2 of a capacitive sensor film;

FIG. 2 shows a cross-sectional view of the sensor film of FIG. 1 along line A-A indicated in FIG. 1;

FIG. 3 shows a top view of a capacitive sensor film comprising a socket arranged at the edge of said capacitive sensor film;

FIG. 4 is a cross-sectional view of the capacitive sensor film of FIG. 3 along line 4-4 indicated in FIG. 3;

FIG. 5 is a cross-sectional view of the capacitive sensor film of FIG. 3 along line 5-5 indicated in FIG. 3;

FIG. 6 shows a diagrammatic plan view of a major surface of another capacitive proximity sensor from which a cover film has been omitted;

FIG. 7 shows an enlarged diagrammatic cross-section of the sensor of FIG. 6, taken on the line 7-7;

FIG. 8 shows a similar view to FIG. 7 but includes the omitted cover film;

FIG. 9 shows a plan view of part of a major surface of a modified capacitive proximity sensor, from which a cover film has been omitted;

FIG. 10 shows an enlarged diagrammatic cross-section of the sensor of FIG. 9, taken on the line 10-10;

FIG. 11 shows a plan view of part of a major surface of another modified capacitive proximity sensor, from which a cover film has been omitted;

FIG. 12 shows an enlarged diagrammatic cross-section of the sensor of FIG. 11, taken on the line 12-12; and

FIGS. 13 and 14 illustrate alternative constructions of part of the sensor shown in FIGS. 9 and 10.

### DETAILED DESCRIPTION

The term “film” as used above and below refers to an article having an extension in two directions which exceeds the extension in a third direction, which is essential normal to said two directions, by a factor of at least 5 and more preferably by at least 10. More generally, the term “film” is used herein to refer to a flexible sheet-like material, and includes sheetings, foils, strips, laminates, ribbons and the like.

The term electrically isolating as used above and below refers to materials having a specific bulk resistivity as measured according to ASTM D 257 of at least 1×10¹² Ohm·centimeters (Ωcm) and more preferably of at least 1×10¹³ scm. The term electrically conductive as used above and below refers to materials having a surface resistivity as measured according to ASTM B193-01 of less than 1 Ohm per square centimeter (Ω/cm²).

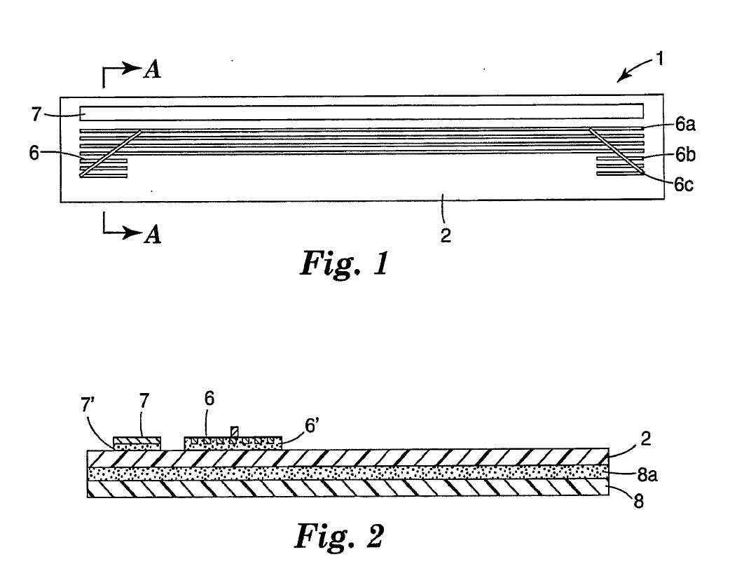

The capacitive proximity sensor 1 of FIGS. 1 and 2 comprises a dielectric film substrate layer 2, the peripheral shape of which is determined by the intended location of the sensor as described further below. In FIG. 1, the substrate layer 2 is shown diagrammatically as being generally rectangular in shape.

The major surface of the substrate layer 2 shown in FIG. 1 carries a sensor conductor 6 and a superguard conductor 7 that are spaced apart on the surface of the substrate layer, and electrically-isolated from one another by the intervening substrate material. The superguard conductor 7 comprises a flat, electrically-conductive strip extending essentially along the length of the substrate layer 2. The sensor conductor 6 exhibits a more complicated design and comprises four, optionally-flattened, conductive strips 6a extending parallel to one another essentially along the length of the substrate layer 2 and, adjacent both ends of the strips 6a, three additional parallel (but shorter), optionally-flattened, electrically-conductive strips 6b forming lobe type regions. The strips 6a, 6b of the sensor conductor are connected together in both lobe regions by electrically-conductive strips 6c extending at an angle across the whole array of strips 6a, 6b. In FIG. 2, the sensor conductor 6 and the superguard conductor 7 are both shown as being attached to the substrate layer 2 by an adhesive 6′, 7′, respectively.

The opposite major surface of the substrate layer 2, not visible in FIG. 1, carries a guard conductor 8 in the form of an electrically-conductive layer that, in some embodiments, covers an area of the substrate corresponding in size at least to that occupied, on the other side, by the sensor conductor 6. In the sensor illustrated in FIGS. 1 and 2, the guard conductor 8 essentially fully covers the surface of the substrate layer 2 to which it is attached (in this case, by an adhesive 8a). The guard conductor 8 is electrically-isolated from the sensor and superguard conductors 6, 7 by the intervening dielectric substrate layer 2.

As so far described, the substrate layer 2, with the sensor conductor 6, the guard conductor 8 and the superguard conductor 7, can be attached to the inside of a bumper of a vehicle to function as a capacitive proximity sensor. To that end, the substrate layer is positioned with the major surface of FIG. 1 (i.e. the surface carrying the sensor and superguard conductors 6, 7) directed outwardly from the vehicle and the other major surface (i.e. the surface carrying the guard conductor 8) directed inwardly towards the vehicle. The conductors 6, 7, 8 are connected to an electronic control unit that can monitor the change that occurs in the capacitance between the sensor conductor 6 and (electrical) ground as the vehicle approaches an external object, and thereby provide an indication to the driver of the distance between the sensor conductor (and, hence, the vehicle) and the object. During the monitoring process, the guard conductor 8 acts as a shield to reduce the sensitivity of the sensor conductor 6 to anything behind it in the direction of the body of the vehicle, while an electrical signal is applied to the superguard conductor 7 to make the guard conductor 8 appear even bigger and so minimize the effect, on the signal from the sensor conductor 6, of water drops running over the bumper in rainy weather conditions. Further information on the operation of a capacitive proximity sensor of that type can be obtained from, for example, WO 01/08925, GB-A-2 374 422, and GB-A-2 400 666 mentioned above. The measurement and processing of signals from a capacitive proximity sensor are described, for example, in WO 02/19,524 of the same Applicant.

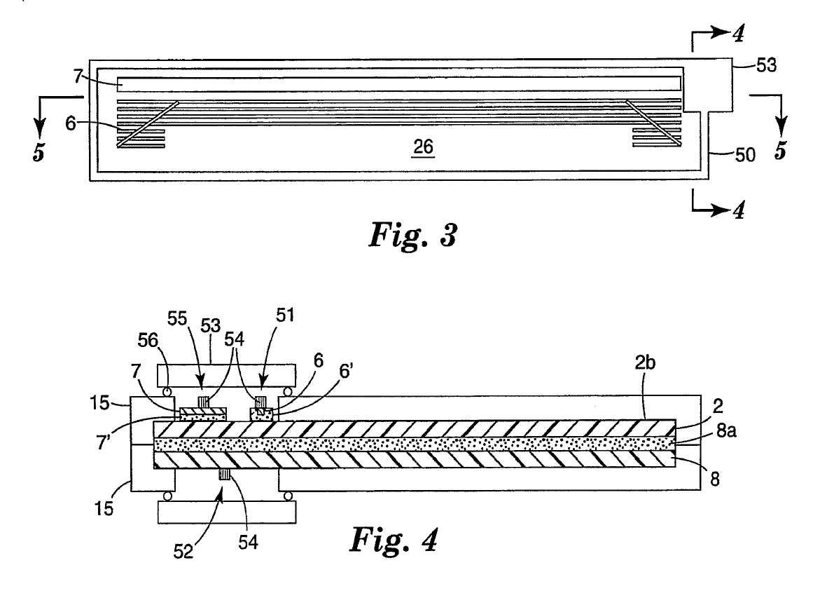

The entire sensor 1 can, if desired, be encased in a protective cover film 15 as shown in FIGS. 3 to 5.

The guard conductor 8, the sensor conductor 6 and, if present, the superguard conductor 7 are electrically contacted from the edge 50 of the sensor 1, as will now be described with reference to FIGS. 3 to 5. The term “edge” denotes the circumferential extension of the sensor in the direction of its thickness.

The sensor conductor 6 and the guard conductor 8 comprise areas 51, 52 respectively that are adjacent to each other and to the edge 50 of the sensor 1 (which, in this case, corresponds to the edge of the substrate layer 2 or, when present, the edge of the protective cover film 15). The term “adjacent to the edge” means that such areas 51, 52 extend so close to the edge 50 of the sensor that they can be easily contacted, for example by means of a socket 53 attached to the edge 50. The shortest distance between the part of areas 51, 52 being electrically contacted and the edge 50 is generally not more than 2 cm, in some embodiments, less than 1 cm and, in some embodiments, less than 5 mm. The term “adjacent to each other” means that the projections of such areas 51, 52 in a direction normal to the major surfaces of the substrate layer 2 are so close to each other that connecting strips 54 contacting the sensor conductor 6 and the guard conductor 8 can be easily integrated into the socket 53. In some embodiments, such projections of areas 51, 52 overlap with each other; the shortest distance between such projections is generally not more than 1 cm and, in some embodiments, less than 5 mm.

The areas 51, 52 should be large enough so that they can be reliably electrically connected to connecting strips 54. In some embodiments, the areas 51, 52 are at least 0.01 mm², in some embodiments, at least 0.04 mm² and, in some embodiments, at least 0.1 mm².

If a superguard conductor 7 is present, it comprises at least one area 55 that is adjacent to the edge 50 of the capacitive sensor 1 and adjacent to the areas 51 and/or 52. The definitions for the terms “adjacent” given above apply correspondingly.

The protective film 15, when present, may be removed in the areas 51, 52, 55 adjacent to the edge 50 after it has been applied. Alternatively, the protective film 15 may be approximately shaped prior to lamination so that the areas 51, 52, 55 are not covered by the protective film upon lamination.

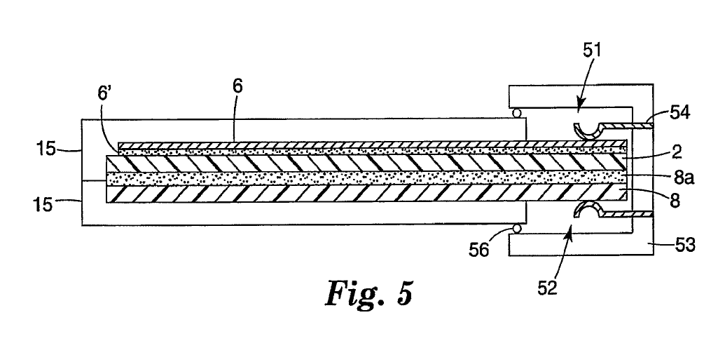

FIGS. 4 and 5 show that the socket 53 comprises O sealing rings 56 around its periphery contacting the surface of the sensor 1. In some embodiments, a complete hermetic seal may be formed between the periphery of the socket and the surface of the capacitive sensor, thus preventing water, air or dust ingress into the connection area. To that end, the socket is applied to the capacitive sensor so that the sealing O-rings 56 are pressurized and form the required hermetic seal. A gasket of adhesive may be used instead of the O sealing rings 56. The socket 53 is applied to the sensor 1 at the edge 50 and provides the spring-loaded connecting strips 54 that form pressure contact with the area 51 of the guard conductor 8 and the area 52 of the sensor conductor 6. If necessary, a conductive strip of the sensor conductor 6 may be extended essentially to the edge 50 to enable contact to the respective connecting strip 54 to be made.

In one method of manufacturing a capacitive sensor of the type shown in FIGS. 3 to 5, a substrate layer 2 is provided first. Then the guard conductor 8 is applied to the rear major surface of the backing layer so that it comprises at least one area 52 that is adjacent to the edge 50 of the substrate layer 2. Likewise, a sensor conductor 6 and, optionally, a superguard conductor 7 is applied to the front major surface of the substrate layer 2 so that the sensor conductor 6 comprises at least one area 51 and the superguard conductor 7 comprises at least one area 55 adjacent to the edge 50 of the substrate layer 2 and adjacent to each other and to the area 51. The socket 53 is then applied to the edge 50 of the substrate layer to connect the conductors 6, 7 and 8 to an electronic control unit (not shown).

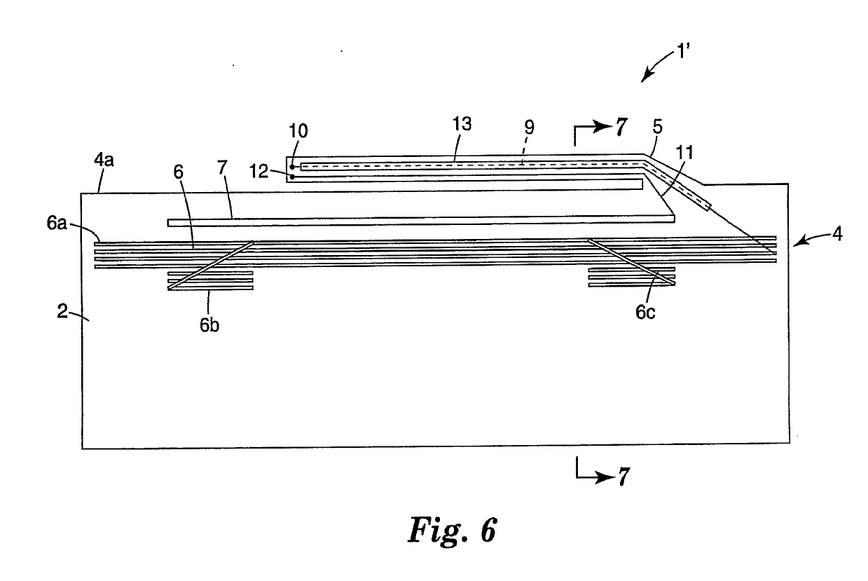

An alternative method of making electrical contact to a sensor of the type shown in FIGS. 1 and 2 will now be described with reference to FIGS. 6 to 8. In this case also, the electrical contact is made at the edge of the sensor.

The sensor 1′ of FIGS. 6 to 8 is generally similar to that of FIGS. 1 and 2, and corresponding components are indicated by the same reference numerals. The main part 4 of the sensor 1′ is additionally provided with an elongate tongue portion 5 extending from one (4a) of its longer sides, the function of which is to facilitate connection of the sensor, guard and superguard conductors 6, 7, 8 to the control unit that monitors the capacitance between the sensor conductor 6 and ground when the proximity sensor 1′ is in use.

As shown in FIG. 6, the tongue portion 5 extends generally parallel to the side 4a of the main part 4 of the substrate layer 2, and is joined to the side 4a towards one end of the latter. A conductive strip 9 extends from the adjacent end of the sensor conductor 6 onto the tongue portion 5 and then along the length of the latter to a terminal 10 at the free end of the tongue portion. To ensure an effective electrical connection between the conductive extension strip 9 and the sensor conductor 6, the extension strip is preferably connected to more than one of the conductive strips 6a, 6b but that it not essential. Similarly, a conductive strip 11 extends from the adjacent end of the superguard conductor 7 onto the tongue portion 5 and then along the length of the latter, parallel to the conductive strip 9, to a terminal 12 at the free end of the tongue portion. On the opposite surface of the substrate layer 2 (not visible in FIG. 6), the guard conductor 8 also extends onto the tongue portion 5 and along the length of the latter, preferably covering an area that corresponds in size at least to that occupied, on the other side, by the conductive strip 9. In the sensor illustrated in FIGS. 6 to 8, the extension 8′ of the guard conductor 8 onto the tongue portion 5 essentially fully covers the respective surface of the latter.

An electrical shield is provided for the conductive extension strip 9 of the sensor conductor 6 by laminating a strip 13 of conductive material over the extension strip, with an intervening strip 14 of dielectric material. The entire sensor 1′, including the tongue portion 5, is then encased in a protective cover film 15 (shown only in FIG. 3). It will be understood that the apparent gaps between the upper cover film 15 and the remainder of the sensor in FIG. 8 are a result of the exaggerated dimensions of the underlying conductive strips 6a, 6b etc. and would not exist in practice.

The elongate tongue portion 5, when constructed as described above, effectively has the form of a flat screened cable extending from the sensor 1′, and can be used to connect the sensor to an electronic control unit at a remote location. In automotive applications, when the sensor is positioned on the bumper of a vehicle, that remote location may be within the vehicle itself. The tongue portion 5 thus eliminates the need to provide a separate, comparatively expensive, coaxial cable in order to connect the sensor to the control unit. Moreover, because the tongue portion 5 is an integral part of the sensor 1′, there are no electrical connection points at the sensor: when the sensor is located on a vehicle bumper, this eliminates the risk of the sensor system being damaged through exposure of such a connection point to the weather or to objects thrown up from the road.

The capacitive sensors 1, 1′ of FIGS. 3 to 8 can each be easily attached, for example by an adhesive, to a suitable supporting surface and are thus easy to install in a location such as the interior of the bumper of a vehicle. The installation is further assisted by the flexibility of the substrate 2 on which the sensor is formed, which facilitates its attachment to curved as well as flat surfaces. It will be understood that the generally rectangular shape of the each of the sensors 1, 1′, is an example only, and that they can be cut to any suitable shape, for example by die-cutting, punching, or laser cutting, and can also be processed to have a contoured shape corresponding to shape of the surface on which they are intended to be mounted. It is also possible to incorporate features such as cuts and darts in the substrate layers 2 so that the sensors can be attached to a three-dimensionally curved surface, such as the inner surface of a vehicle bumper, without forming undesirable creases.

Suitable materials for the substrate layers 2 of the sensor 1, 1′, include, for example, polymeric films and layers, paper films and layers, layers of non-wovens, laminates (such as, for example, polyacrylate foams laminated on both sides with polyolefin films, and papers laminated or jig-welded with polyethylene terephthalate) and combinations thereof. Useful polymeric films and layers include, for example, polyolefin polymers, monoaxially oriented polypropylene (MOPP), biaxially oriented polypropylene (BOPP), simultaneously biaxially oriented polypropylene (SBOPP), polyethylene, copolymers of polypropylene and polyethylene, polyvinylchloride, copolymers having a predominant olefin monomer which may be optionally chlorinated or fluorinated, polyester polymers, polycarbonate polymers, polymethacrylate polymers, cellulose acetate, polyester (e.g. biaxially oriented polyethylene terephthalate), vinyl acetates, and combinations thereof. Useful substrate materials may be subjected to an appropriate surface modification technique including, for example, plasma discharge techniques including corona discharge treatment and flame treatment, mechanical roughening and chemical primers.

The conductive strips of the sensor conductors 6 (and, in the case of the sensor 1′, the extension 9 of the sensor conductor on the tongue portion 5) may be formed from any suitable electrically-conductive material, for example copper, and may be applied to the substrate 2 by an adhesive (as illustrated only for the sensor 1). As an alternative, the sensor conductor 6 may be formed by vapour deposition of a suitable metal onto the substrate 2, or it may be formed from a foil that is bonded to the substrate. As yet a further alternative, the sensor conductor 6 may be formed by removing zones of material from an electrically-conductive layer on the substrate 2, as described in our co-pending European patent application No. 06001155.8 of 19 Jan. 2006. The sensor conductor 6 may assume a variety of shapes, although a discontinuous arrangement of conductive areas, such as the arrangement of conductive strips described above, exhibits an especially advantageous sensitivity and may be preferred.

The thickness of the sensor conductor 6 (i.e. its height above the substrate layer 2) may vary widely depending on the method by which it is manufactured. A sensor conductor comprising flattened metal strips will have a thickness of typically between 20 and 200 micrometers (μm) and, in some embodiments, between 25 and 100 nm. A sensor conductor obtained by vacuum metal vapour deposition may be as thin as 200-800 Angstroms (Å) and, in some embodiments, 300-500 Å. When using an aluminum foil for the sensor conductor, it may have a thickness of from 1-100 μm, in some embodiments, 2-50 μm and, in some embodiments, 3-30 μm.

The superguard conductor 7 and its extension 11 may be formed from any suitable electrically-conductive material in any of the ways described above for the sensor conductor 6 and its extension 9, and will have a similar resulting thickness. The superguard conductor 7, as already mentioned, is not an essential component of the sensor 1 but, if present, may assume a variety of shapes and, in automotive applications, may be arranged (relative to the road level) above or below the sensor conductor 6.

The guard conductor 8 (and, in the case of the sensor 1′, its extension 8′ on the tongue portion 5) may be formed from any suitable electrically-conductive material, for example aluminium. It may be formed, for example, by adhesively-bonding a metal foil to the substrate 2 or by applying a metallic layer directly to the substrate, for example by vacuum metal vapour deposition.

The thickness of the guard conductor 8 and its extension 8′ may vary widely depending on the method by which they are formed on the substrate 2. A metallic layer obtained by vacuum vapour deposition may be as thin as 200-800 Å and, in some embodiments, 300-500 Å. A metal foil, on the other hand, may have a thickness of from 1-100 μm, in some embodiments, 2-50 μm and, in some embodiments, 3-30 μm.

The electrical shield 13 for the conductive extension strip 9 on the tongue portion 5 may be formed from any suitable electrically-conductive material. It may, for example, comprise a metallic foil that is adhered to the tongue portion by an adhesive. That adhesive may provide the dielectric material 14, or an extra layer of dielectric material may be provided.

The protective cover film 15 that encases the sensor 1 or 1′ is a polymeric film that is applied to the sensor by, for example, an adhesive or heat-lamination. In some embodiments, the dimensions of the film exceed those of the substrate 2 to provide a border that will form an edge seal around the sensor to protect, in particular, the edges of the guard conductor 8 (and, in the case of the sensor 1′, its extension 8′) against corrosion. The border may have a width of 1-50 mm, in some embodiments, of 1-40 mm and, in some embodiments, of 2-20 mm.

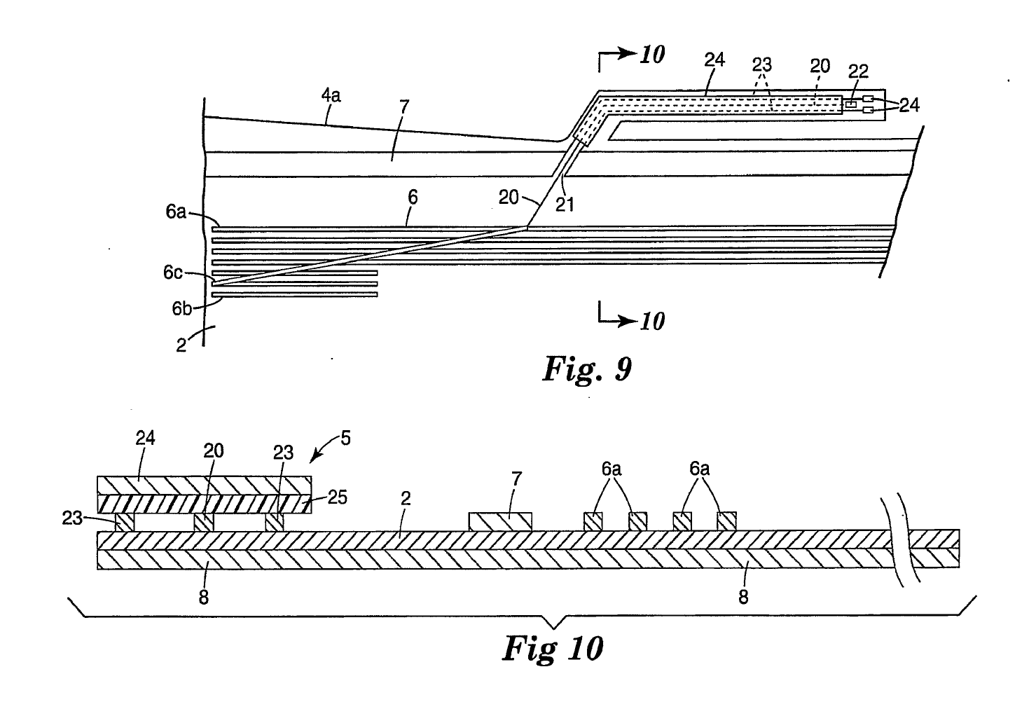

FIGS. 9 and 10 show a modification of the sensor 1′, in particular an alternative layout for the extensions of the sensor and superguard connectors 6, 7 onto the tongue portion 5 of the substrate 2. In this case, the tongue portion 5 is shown extending in the opposite direction from the long edge 4a of the main portion 4 of the substrate 2 but it will be apparent from the following description that this is not essential. In this layout, the extension of the sensor conductor 6 onto the tongue portion 5 is by means of a conductive strip 20 that is a continuation of one of the strips 6c that connects together the various strips 6a, 6b of the sensor conductor. The conductive strip 20 extends onto the tongue portion 5 through a break 21 in the superguard conductor 7, and then extends along the length of the tongue portion to a terminal 22. As a consequence of the break 21 in the superguard conductor 7, two conductive strips 23 (one on each side of the break 21) are required to extend from the superguard conductor 7 onto the tongue portion 5 and then along the length of the latter, parallel to the conductive strip 20, to respective terminals 24. On the opposite surface of the substrate layer 2 (not visible in FIG. 8), the guard conductor 8 has the same configuration as in FIGS. 6 to 8, and extends similarly onto the tongue portion 5.

An electrical shield is provided for the extension strip 20 of the sensor conductor 6 by laminating a strip 24 of conductive material over the strip, with an intervening strip 25 of dielectric material. In this case, the conductive and dielectric strips 24, 25 also cover the extension strips 23 of the superguard conductor 7 but that is not essential. The entire sensor 1, including the tongue portion 5, is then encased in a protective cover film (not shown) as described above with reference to FIG. 8. It will be understood that the apparent gaps between the strips 24, 25 and the remainder of the tongue portion 5 in FIG. 10 are a result of the exaggerated dimensions of the underlying conductive strips 20, 23 and would not exist in practice.

The layout shown in FIGS. 9 and 10 allows a greater degree of choice in the positioning of the tongue 5 on the sensor, and also enables a more compact arrangement to be obtained if desired.

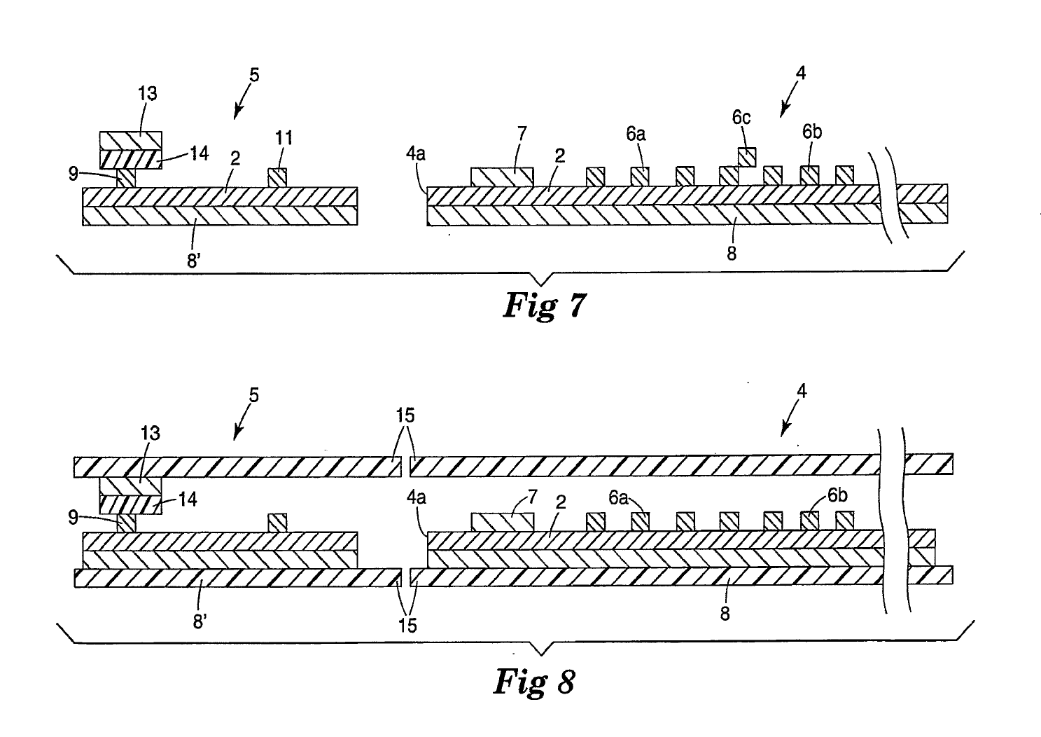

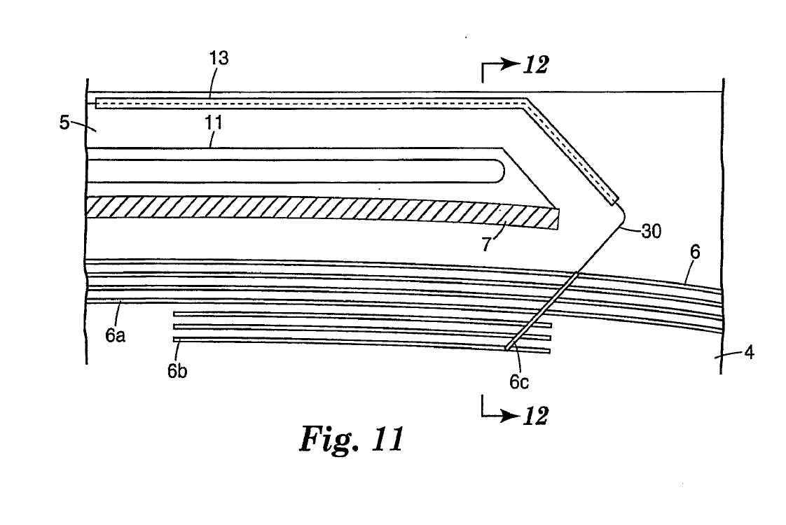

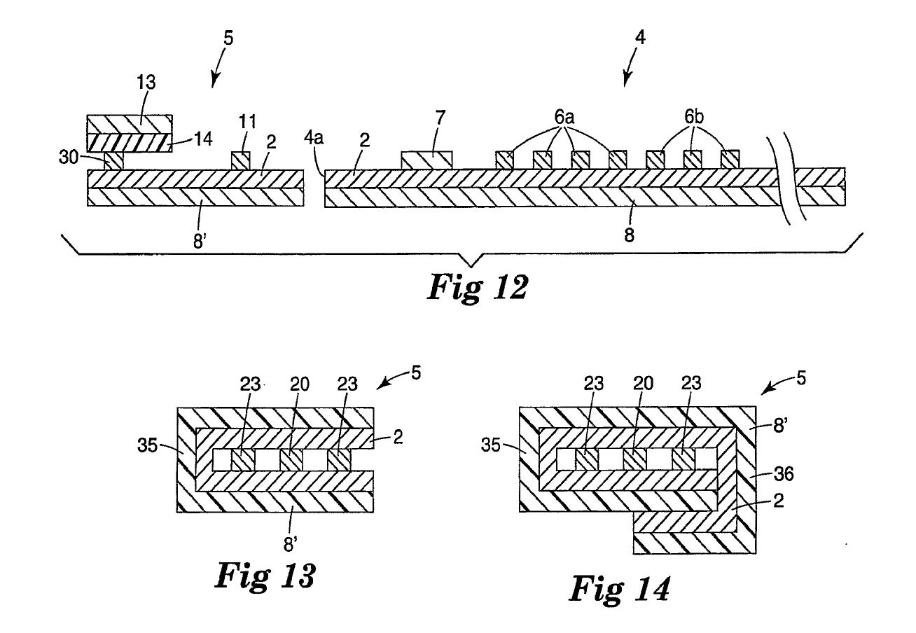

FIGS. 11 and 12 show another modification of the sensor shown in FIGS. 6 and 7, in which the extension of the sensor conductor 6 onto the tongue portion 5 is by means of a conductive strip 30 that is again a continuation of one of the strips 6c that connects together the various strips 6a, 6b of the sensor conductor. In this case, however, to avoid the need for a break in the superguard conductor 7 as in FIG. 10, the strip 6c is reoriented so that it extends at a different angle across the array of parallel conductive strips 6a, 6b, enabling the strip 30 to pass around one end of the sensor conductor 7. The remaining components of FIGS. 11 and 12 are as described above with reference to FIGS. 6 and 7, and carry the same reference numerals.

Alternative methods of forming the tongue portion 5 into the equivalent of a flat screened cable are illustrated in FIGS. 13 and 14. These alternative methods eliminate the need to apply the separate shielding and dielectric layers 13,14 (FIGS. 7 and 12) and 24,25 (FIG. 10). In both methods, the substrate layer 2 of the tongue portion 5, with the attached extension 8′ of the guard conductor 8, are extended outwards on the side of the tongue portion remote from the main body 4 of the sensor. When the conductive strips (9,11; 20;23; or 30,11) are in position on the tongue portion, the extended portion of the substrate layer (with the attached extension 8′ of the guard conductor) is folded around over the strips to enclose and shield them. FIG. 13 shows a single fold 35 being used, which has the effect of bringing together the edges of the tongue portion 5, while FIG. 14 shows the tongue portion being wrapped-around further, entailing an additional fold 36. FIGS. 13 and 14 show three strips on the tongue portion 5, as in the sensor of FIGS. 9 and 10, but the arrangement is equally applicable to the sensors of FIGS. 6 to 8, and 11 and 12. Again, it will be understood that the apparent gaps between the folded parts of the tongue portion 5 in FIGS. 13 and 14 are a result of the exaggerated dimensions of the conductive strips 20, 23 and would not exist in practice.

If the sensors of FIGS. 6, 9 and 11 are employed in a situation in which the electronic control unit is adjacent the sensor, the electrical shield 13, 24 on the tongue portion 5 can be omitted.

Sensors of the type shown in FIGS. 6 to 14 are also described and claimed in our patent application of even date entitled “Capacitive proximity sensor with connector tongue portion” (attorney docket No. 62571).

The capacitive proximity sensors described above with reference to the drawings can be easily installed and, because they are flexible, they can be applied to shaped substrates having, for example, curved surfaces. It is particularly advantageous that the capacitive sensors can be electrically contacted in an easy and reliable way. In view of these advantages the sensors are especially suited for use in the automotive industry.

It will be understood that the particular configurations shown in the drawings for the sensor and guard conductors and the optional superguard conductor are for the purposes of illustration only and are not an essential feature of the invention. The proximity sensors described herein with reference to the drawings are particularly appropriate for use on vehicle bumpers but the manner in which electrical connection is made from one edge of the substrate layer to the sensor and guard conductors (and, when present, the superguard conductor) is applicable to capacitive proximity sensors intended for use in other applications and to capacitive proximity sensors with differently-configured conductors including, for example, those with a sensor conductor of serpentine or spiral form or with two interdigitated sensor conductors, or with a multiplicity of guard conductors.

1-13. (canceled)

14. A capacitive proximity sensor for mounting to a body for sensing external objects, the sensor comprising a dielectric film substrate having front and rear major surfaces which, in use of the sensor, face respectively outward from and towards the body; a sensor conductor on the front major surface, and a guard conductor on the rear major surface to provide an electrical shield for the sensor conductor;
wherein electrical contact can be made to the sensor conductor and to the guard conductor at the edge of the film substrate.

15. The sensor of claim 14, further comprising a superguard conductor on the front major surface of the substrate; wherein electrical contact can also be made to the superconductor at the edge of the film substrate at which the sensor and guard conductors can be contacted.

16. The sensor of claim 14, in which the sensor and guard conductors each comprise respective areas adjacent to each other and to the edge of the film substrate at which electrical contact can be made to the conductors.

17. The sensor of claim 16, further comprising a protective coating over the front and rear major surfaces of the sensor, the protective coating being absent over at least part of the said areas whereby electrical contact can be made to the conductors.

18. The sensor of claim 14, in which the sensor and guard conductors are provided with electrical connectors from a socket which is arranged at the edge of the film substrate.

19. The sensor of claim 18, in which the socket is sealed against at least one of the major surfaces of the sensor.

20. The sensor of claim 14, wherein the substrate comprises a tongue portion which extends from a peripheral edge of a main part of the substrate, on which the sensor and guard conductors are located; and wherein the sensor and guard conductors extend onto the tongue portion to provide respective terminals by which external electrical connections can be made to the sensor.

21. The sensor of claim 20, further comprising a superguard conductor on the front major surface of the substrate, wherein the superguard conductor also extends onto the tongue portion to provide a respective terminal by which an external electrical connection can be made to the superguard conductor.

22. The sensor of claim 20, further comprising an electrical shield for the extension of the sensor conductor on the tongue portion.

23. The sensor of claim 22, further comprising a superguard conductor on the front major surface of the substrate, wherein the superguard conductor also extends onto the tongue portion to provide a respective terminal by which an external electrical connection can be made to the superguard conductor and which also comprises an electrical shield for the extension of the superguard conductor on the tongue portion.

24. The sensor of claim 22, in which the whole of the front major surface of the tongue portion is covered by an electrical shield.

25. The sensor of claim 20, in which the extension of the guard conductor covers the whole of the rear major surface of the tongue portion, and the tongue portion is folded over so that the sensor conductor is shielded by the folded-over part of the guard conductor.

26. The sensor of claim 20, in which the tongue portion forms a cable for connecting the conductors of the sensor to a remotely-located electronic control unit.
